(19) United States
(12) Patent Application Publication
(10) Pub. No.: US 2020/0309829 A1
(43) Pub. Date: Oct. 1, 2020

(54) On-line monitoring system for the performance of the measurement equipment in the entire power grid based on wide-area synchronous measurement

(71) Applicant: Dake He, Auburn, AL (US)

(72) Inventors: Dake He, Auburn, AL (US); Kun Liu, Chengdu (CN); Bing Ai, Chengdu (CN); Fuzhou Zhang, Chengdu (CN); Qiang Shi, Chengdu (CN); Xianshun Chen, Chengdu (CN); Xiang Zhang, Chengdu (CN)

(73) Assignees: Dake He; Kun Liu

(21) Appl. No.: 16/371,124

(22) Filed: Apr. 1, 2019

(51) Int. Cl. G01R 22/06; G01R 22/10

(52) U.S. Cl. CPC G01R 22/068; G01R 22/10

(57) ABSTRACT

The invention discloses an on-line monitoring system for the performance of the measurement equipment in the entire power grid based on wide-area synchronous measurement, including a number of capacitive voltage transformers (CVT), electronic voltage transformers (EVT), electronic current transformers (ECT), electromagnetic potential transformers (PT), electromagnetic current transformers (CT), secondary circuits, electric energy meters, energy acquisition terminals, merging units, switches, clock synchronization systems, long-distance transmission line and other operating equipment. It also includes CVT insulation parameter monitoring module, CT oil pressure sensor, environmental parameter monitoring module, clock synchronization module, wide-area synchronous monitoring system consist of online monitoring apparatus, data transmission channel, installed in all substations of the power grid, as well as analysis and evaluation system of acquisition master station.

CT, CVT and PT are connected to the on-line monitoring apparatus separately. EVT, ECT, CVT parameter acquisition module, CT oil pressure sensor and environmental parameter monitoring module are connected to the merging unit. The merging unit is connected to the on-line monitoring apparatus separately. The clock synchronization module is connected to the merging unit and the on-line monitoring apparatus respectively. The On-line monitoring apparatus can synchronously monitor and alarm the insulation performance, error characteristics and environmental parameters of multiple transformers, electric energy meters and secondary circuits, and complete on-line calibration of electric energy meters and group calibration of instrumentational transformers, and transmit the data to the acquisition master station through mature protocol and data transmission channels for energy data acquisition and equipment state monitoring. The on-line monitoring apparatus and merging unit in the entire network are synchronized by GPS clock synchronization system, so that the data of the entire network can be acquired synchronously. The overall performance of various measurement equipment is evaluated using related analytical techniques based on big data technologies.

### TECHNICAL FIELD

The invention relates to the technical field of electric power equipment monitoring, specifically an on-line monitoring and evaluation system for the error and insulation performance of a measurement equipment consisting of a transformer, an electric energy meter and a secondary circuit based on wide-area synchronous measurement technology.

### TECHNICAL BACKGROUND

In the power system today, capacitive voltage transformer (CVT), electronic voltage transformer (EVT), electronic current transformer (ECT), electromagnetic potential transformer (PT), electromagnetic current transformer (CT) and electric energy meter are widely used. The accuracy, stability and reliability of their measurement will directly affect the fairness of electric energy measurement and the safety of power grid operation. The performance and reliability of CVT, EVT, ECT, PT and CT are influenced by various factors due to their own structural characteristics. Meanwhile, the calibration period of important gateway energy meters is three months. The workload of on-site calibration of the transformers is large and requires multi-professional cooperation. Therefore, the state monitoring and evaluation of measurement equipment is an inevitable development trend in the future.

At present, the research on online monitoring system for transformers and electric energy meters has been carried out. However, there are many problems, such as single acquisition value, small acquisition volume, separate deployment of performance monitoring apparatuses for measurement and insulation, insufficient depth of data application, high cost and low reliability.

At the same time, data transmission passes through dedicated channel, where communication security is a severe problem. Especially, due to the lack of synchronous measurement and analysis of the operation data of the entire power grid, it is not possible to accurately evaluate the voltage drop of relevant equipment and lines. In order to provide statistical and analytical support for government decision-making and quality supervision, and provide data analysis and application services for energy saving, consumption reduction and quality improvement of enterprises, it is necessary to strengthen the construction of integrated data acquisition and monitoring system for energy measurement, to improve on-line monitoring and intelligent diagnosis technology for measurement equipment, and to realize gradually on-line acquisition and monitoring of energy measurement data in various industries, fields and enterprises.

Therefore, in order to ensure the safe operation of power system and the accuracy and reliability of electric energy measurement, it is of great significance to develop a highly cost-effective on-line monitoring apparatus and evaluation system for the entire power grid, which also integrates the main performance indicators of transformers and electric energy meters.

### SUMMARY OF THE INVENTION

The invention aims at the deficiencies of the prior art, and provides an online monitoring system for error and insulation performance of a measurement equipment consisting of transformer in entire power grid, electric energy meters and secondary circuits based on wide-area synchronous measurement. Wherein, the on-line monitoring apparatus can synchronously monitor the error characteristics, insulation performance and environmental parameters of various transformers, electric energy meters and secondary circuits of the whole station, complete the on-line calibration of electric energy meters and the group calibration of the instrumentational transformers, and transmit the data to the acquisition master station through mature protocol and data transmission channels for energy data acquisition and equipment state monitoring.

The on-line monitoring apparatuses and merging units in the entire power grid are synchronized by the GPS clock synchronization system. Thus, the synchronous data acquisition of the entire power grid can be realized. The master station monitors and evaluates the error characteristics, insulation performance and environmental parameters of various transformers, electric energy meters, secondary circuits and line losses of the entire power grid based on the data analysis for the entire power grid.

The invention is realized by the following technical scheme:

The on-line monitoring system for the performance of the measurement equipment in the entire power grid based on wide-area synchronous measurement includes a number of capacitive voltage transformers (CVT), electronic voltage transformers (EVT), electronic current transformers (ECT), electromagnetic potential transformers (PT), electromagnetic current transformers (CT), secondary circuits, electric energy meters, energy acquisition terminals, merging units, switches, clock synchronization systems, long-distance transmission line and other operating equipment. It also includes CVT insulation parameter monitoring module, CT oil pressure sensor, environmental parameter monitoring module, clock synchronization module, wide-area synchronous monitoring system consist of online monitoring apparatus, data transmission channel, installed in all substations of the power grid, as well as analysis and evaluation system of acquisition master station. The online monitoring apparatus is the core of the system, which collects the secondary voltage and current values of PT and CT, receives synchronous sampling values of EVT and ECT, receives the synchronous samplings from CVT insulation parameter monitoring module, CT oil pressure sensor and environmental parameter monitoring module, and stores and uploads to the monitoring master station after relevant calculations, meanwhile completes the online calibration of the energy meters.

The said online monitoring apparatus comprises CPU processor, first FPGA chip, second FPGA chip, clock unit, signal conditioning and A/D conversion unit, communication module, memory, etc. The first FPGA chip, the second FPGA chip and the clock unit are all connected with the CPU processor; the A/D conversion unit is connected with the first FPGA chip; the analog secondary circuits of the said CVT, PT, and CT are connected with the A/D conversion unit after signal conditioning; EVT and ECT are connected with merging unit; the merging unit is connected to the switches according to the voltage levels; the switch output end is connected with the second FPGA chip in the online monitoring apparatus; CVT insulation parameter acquisition module, CT oil pressure sensor and environmental parameter monitoring module are connected with merging unit; the output pulse of the said electric energy meter is connected to the first FPGA chip, and the first FPGA chip generates standard pulses according to the calculated energy; the clock synchronization module is connected with the merging unit and the clock unit in the on-line monitoring apparatus respectively to ensure synchronized data acquisition for the entire substation; CPU processor controls RJ45, USB, RS485, ST, SC interfaces through communication control module, and communicate with related equipment after data encryption through EASM;

The CPU of the transformer online monitoring apparatus synchronously sampled and calculated the amplitude, phase, insulation and environmental parameters of each transformer through the first and second FPGA chips. It connects with the energy data acquisition terminal through RS485 interface. The energy data acquisition terminal transmitted data to the acquisition master station through optical fiber and wireless private network. Meanwhile, the CPU can be directly connected with the central master station for equipment state evaluation through optical fiber and wireless module. The central master station evaluates and analyses the operation performance of the measurement equipment according to the received data. The on-line monitoring apparatus and merging unit are synchronized by clock synchronization module, and the on-line monitoring apparatus and merging unit in the entire network are synchronized by GPS clock synchronization system, so that the data of the entire network can be acquired synchronously.

Preferably, the CPU, the first FPGA chip and the second FPGA chip of the said online monitoring apparatus are connected with RAM, and the first and the second FPGA chips are connected with each other, and each FPGA chip call the data stored in any RAM to calculate the relevant parameters.

Preferably, choose 8-channel 24-bit ADS 1278 for the said A/D conversion unit, EP4CE10E2217 for the said first and second FPGA chips, H57V2562 for the said RAM, and AM3359 for the said CPU.

Preferably, the insulation parameter acquisition module of CVT is a measuring transformer for measuring the capacitive current of CVT. It can be built inside or installed outside the CVT. The relative dielectric loss and capacitance can be calculated by measuring the capacitive current and PT instantaneous value of the same phase of the CVT.

Preferably, voltage and current input channels inside the on-line monitoring apparatus can be configured arbitrarily according to the requirements of substations with different voltage levels.

Preferably, the online monitoring apparatus can be arbitrarily expanded depending on the number of intervals of the substation, while ensure synchronous sampling of equipment in the entire substation.

Preferably, the CPU can directly connect with the central master station for equipment state evaluation through the optical fiber and the wireless module to meet the professional requirements for operation and maintenance. It can also connect with the electric energy acquisition terminal through the RS485 interface, and establish data connection with the acquisition master station through energy acquisition terminal to meet the requirements of the metrology specialty.

Preferably, the clock synchronization module is used to control synchronous sampling, and the punctual error of the online monitoring apparatus is less than 4 us/10 min.

Preferably, IEC 61850-9-1 and IEC 61850-9-2 protocols and the customization of environmental communication between the merging unit and the second FPGA chip are the adopted.

Preferably, the steps of parameter sampling and calculation of the said CPU processor include:

Step 1: Synchronously acquire the instantaneous values of 10 continuous cycles of up to 90 CVTs, PTs and CTs. The acquisition sampling frequency shall be above 256 points/cycle. The amplitude and phase of each transformer, the effective current/voltage value of each circuit and the secondary voltage drop of electromagnetic potential transformer PT shall be calculated. The accuracy of analog measurement shall be 0.05%, the resolution shall be 0.01%. The time interval of acquisition and analysis is 5 minutes;

Step 2: Analyze CVT capacitive current and ambient temperature and humidity parameters, which are digitized locally and uploaded by merging unit. The instantaneous values of CVT and PT in the same phase are used to calculate dielectric loss and capacitance.

Step 3: Calculate the short-term electric energy by using the instantaneous values of the voltage transformer and the current transformer. Calibrate the error of the electric energy meters by inspecting the low-frequency pulses of the electric energy meters. The calibration time is determined dynamically according to the current magnitude to ensure the accurate calibration of the meter in the full current range.

Step 4: According to the comparison of the vector sum of three-phase current of the same voltage level with the zero-sequence current, determine whether the error of the current transformer is out of tolerance;

Step 5: Configure the amplitude difference, phase difference and channels for dielectric loss calculation between any two transformers of the same voltage level. All acquired data is time stamped for storage.

Preferably, the evaluation and analysis steps of the acquisition master station include:

Step 1. Set the alarm value range of each measured value and the difference of the same measured value, and send out alarm to relevant professional and management personnel through text message and APP according to the measured value;

Step 2: Analyze the three-dimensional relationship between angular difference, ratio difference, dielectric loss with temperature and humidity at any period to form a three-dimensional figure;

Step 3: Calculate the long-term stable errors of the angular difference, the ratio difference, and the dielectric loss;

Step 4: Analyze the performance change of equipment from the same manufacturer, and discover the inherent defects of the equipment;

Step 5: Evaluate the comprehensive error of the measurement equipment by parameters such as transformer angular difference, ratio difference, electric energy meter error, secondary circuit voltage drop and the like;

Step 6: Calculate the voltage drop of the long-distance transmission line according to the data acquired synchronously by the entire network, and evaluate the line loss and the line parameters. Evaluate the transformer error by the difference between the secondary values of the transformers between two substations.

The invention has the following advantages and benefits:

1. This invention, the on-line performance monitoring system of the measurement equipment based on wide-area synchronous measurement, can simultaneously monitor the insulation performance, error characteristics and environmental parameters of multiple transformers, electric energy meters, secondary circuits and long-distance transmission lines in the entire power grid, thus saving the cost of monitoring data acquisition and improving the reliability.

2. This invention, the on-line performance monitoring system of the measurement equipment based on wide-area synchronous measurement, realizes data transmission utilized the existing energy acquisition system and equipment state evaluation system, such that the security evaluation for the information system does not needed, which ensures information security while reducing the cost for data transmission.

3. This invention, the on-line performance monitoring system of the measurement equipment based on wide-area synchronous measurement, can evaluate the overall performance of transformers, electric energy meters, secondary voltage drop, voltage drop of long-distance transmission lines, line loss and line parameters. This invention can provide statistical and analytical support for government decision-making and quality supervision, and provide data analysis and application services for energy saving, consumption reduction and quality improvement of enterprises, which can be realized by strengthening the construction of integrated data acquisition and monitoring system for energy measurement, improving the on-line monitoring and intelligent diagnosis technology for measurement equipment, and realizing gradually on-line acquisition and monitoring of energy measurement data in various industries, fields and enterprises.

### DESCRIPTION OF THE DRAWINGS

The attached drawings described herein are used to provide a further understanding of embodiments of the present invention, which form part of the present application, and are not intended to limit the embodiments of this invention. In the drawings:

FIG. 1 is a system structure diagram of the present invention.

FIG. 2 is a schematic diagram of the dielectric loss measurement of the present invention.

### SPECIFIC IMPLEMENTATION METHODS

In order to make the purpose, technical scheme and advantages of the present invention more comprehensible, the present invention will be further described in detail below with reference to the embodiments and drawings. The illustrative embodiments of the invention and the description thereof are merely illustrative of the invention and are not intended to limit the invention.

### Implementation Example

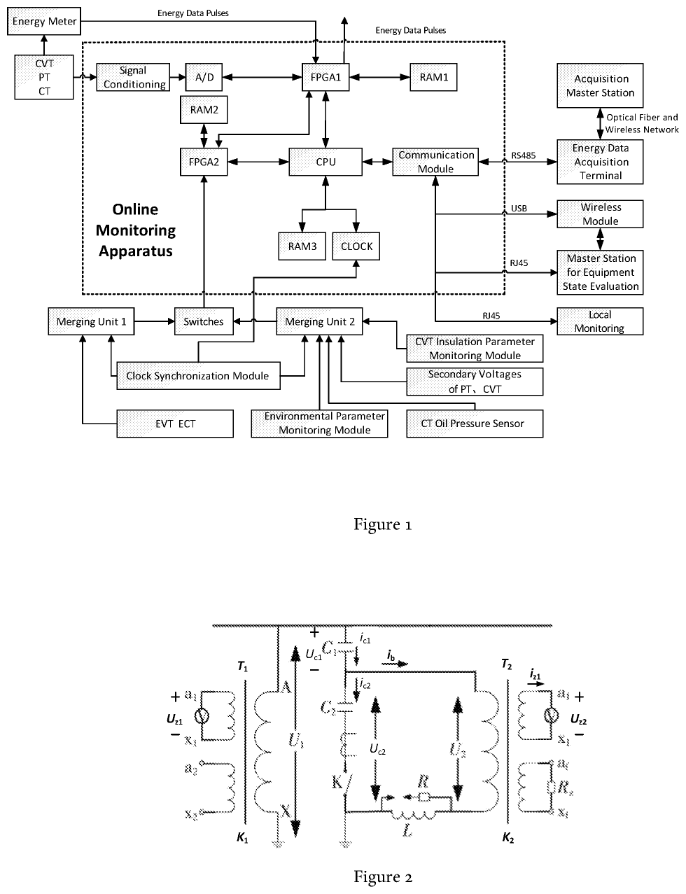

As shown in FIG. 1, The on-line monitoring system for the performance of the measurement equipment in the entire power grid based on wide-area synchronous measurement includes a number of capacitive voltage transformers (CVT), electronic voltage transformers (EVT), electronic current transformers (ECT), electromagnetic potential transformers (PT), electromagnetic current transformers (CT), secondary circuits, electric energy meters, energy acquisition terminals, merging units, switches, clock synchronization systems, long-distance transmission line and other operating equipment. It also includes CVT insulation parameter monitoring module, CT oil pressure sensor, environmental parameter monitoring module, clock synchronization module, wide-area synchronous monitoring system consist of online monitoring apparatus, data transmission channel, installed in all substations of the power grid, as well as analysis and evaluation system of acquisition master station. The online monitoring apparatus is the core of the system, which collects the secondary voltage and current values of PT and CT, receives synchronous sampling values of EVT and ECT, receives the synchronous samplings from CVT insulation parameter monitoring module, CT oil pressure sensor and environmental parameter monitoring module, and stores and uploads to the monitoring master station after relevant calculations, meanwhile completes the online calibration of the energy meters.

The said online monitoring apparatus comprises CPU processor, first FPGA chip, second FPGA chip, clock unit, signal conditioning and A/D conversion unit, communication module, memory, etc. The first FPGA chip, the second FPGA chip and the clock unit are all connected with the CPU processor; the A/D conversion unit is connected with the first FPGA chip; the analog secondary circuits of the said CVT, PT, and CT are connected with the A/D conversion unit after signal conditioning; EVT and ECT are connected with the first merging unit; the first merging unit is connected to the switches according to the voltage levels; the switch output end is connected with the second FPGA chip in the online monitoring apparatus. CVT insulation parameter acquisition module, CT oil pressure sensor and environmental parameter monitoring module are connected to the second merging unit, the second merging unit is connected to the switches according to the voltage levels; the switch output end is connected to the second FPGA chip in the online monitoring apparatus. The output pulse of the said electric energy meter is connected to the first FPGA chip, and the first FPGA chip generates standard pulses according to the calculated energy; the clock synchronization module is connected with the merging units and the clock unit in the on-line monitoring apparatus respectively to ensure synchronized data acquisition for the entire substation; CPU processor controls RJ45, USB, RS485, ST, SC interfaces through communication control module, and communicate with related equipment after data encryption through EASM.

Wherein: the secondary voltage of the PT, the secondary voltage of the CVT, and the secondary current of the CT are signal-conditioned and converted into digital quantities by the A/D conversion unit, and then input to the first FPGA chip for processing. The secondary voltage of the EVT, the secondary current of the ECT, the CVT capacitive current of the CVT parameter acquisition module, CT oil pressure, and the temperature and humidity of the environmental parameter monitoring module are input to the second FPGA chip through the first and second merging units and switches for processing. The errors, insulation and environmental parameters of each instrumentational transformer are sampled and calculated synchronously by CPU, the first FPGA chip and the second FPGA chip in the transformer on-line monitoring apparatus, which is connected with the energy data acquisition terminal through RS485 interface. The energy data acquisition terminal transmits data to the acquisition master station through optical fiber and wireless module. The acquisition master station evaluates and analyzes the performance of each transformer based on the received data. The CPU can directly connect to the central master station for equipment state evaluation through the optical fiber and the wireless module. The central master station evaluates and analyzes the performance of the measurement equipment based on the received data. The online monitoring apparatus and the merging unit are clock-synchronized by the clock synchronization module, and the GPS clock synchronization system synchronizes the online monitoring apparatuses and the merging units of the entire power grid, thereby realizing synchronous data acquisition of the entire network.

Preferably, the CPU, the first FPGA chip and the second FPGA chip of the said online monitoring apparatus are connected to RAM, and the first and the second FPGA chips are connected with each other, and each FPGA chip call the data stored in any RAM to calculate the relevant parameters.

Preferably, choose 8-channel 24-bit ADS 1278 for the said A/D conversion unit, EP4CE10E2217 for the said first and second FPGA chips, H57V2562 for the said RAM, and AM3359 for the said CPU.

Preferably, as illustrated in FIG. 2, the insulation parameter acquisition module of CVT is a measuring transformer for measuring the capacitive current of CVT. It can be built inside or installed outside the CVT. The relative dielectric loss and capacitance can be calculated by measuring the capacitive current and PT instantaneous value of the same phase of the CVT.

Preferably, voltage and current input channels inside the on-line monitoring apparatus can be configured arbitrarily according to the requirements of substations with different voltage levels.

Preferably, the online monitoring apparatus can be arbitrarily expanded depending on the number of intervals of the substation, while ensure synchronous sampling of equipment in the entire substation.

Preferably, the CPU can directly connect with the central master station for equipment state evaluation through the optical fiber and the wireless module to meet the professional requirements for operation and maintenance. It can also connect with the electric energy acquisition terminal through the RS485 interface, and establish data connection with the acquisition master station through energy acquisition terminal to meet the requirements of the metrology specialty.

Preferably, the clock synchronization module is used to control synchronous sampling, and the punctual error of the online monitoring apparatus is less than 4 us/10 min.

Preferably, IEC 61850-9-1 and IEC 61850-9-2 protocols and the customization of environmental communication between the merging unit and the second FPGA chip are the adopted.

Preferably, the steps of parameter sampling and calculation of the said CPU processor include:

Step 1: Synchronously acquire the instantaneous values of in continuous cycles of up to 90 CVTs, PTs and CTs. The acquisition sampling frequency shall be above 256 points/cycle. The amplitude and phase of each transformer, the effective current/voltage value of each circuit and the secondary voltage drop of electromagnetic potential transformer PT shall be calculated. The accuracy of analog measurement shall be 0.05%, the resolution shall be 0.01%. The time interval of acquisition and analysis is 5 minutes;

Step 2: Analyze CVT capacitive current and ambient temperature and humidity parameters, which are digitized locally and uploaded by merging unit. The instantaneous values of CVT and PT in the same phase are used to calculate dielectric loss and capacitance.

Step 3: Calculate the short-term electric energy by using the instantaneous values of the voltage transformer and the current transformer. Calibrate the error of the electric energy meters by inspecting the low-frequency pulses of the electric energy meters. The calibration time is determined dynamically according to the current magnitude to ensure the accurate calibration of the meter in the full current range.

Step 4: According to the comparison of the vector sum of three-phase current of the same voltage level with the zero-sequence current, determine whether the error of the current transformer is out of tolerance;

Step 5. Configure the amplitude difference, phase difference and channels for dielectric loss calculation between any two transformers of the same voltage level. All acquired data is time stamped for storage.

Preferably, the evaluation and analysis steps s of the acquisition master station include:

Step 1: Set the alarm value range of each measured value and the difference of the same measured value, and send out alarm to relevant professional and management personnel through text message and APP according to the measured value;

Step 2: Analyze the three-dimensional relationship between angular difference, ratio difference, dielectric loss with temperature and humidity at any period to form a three-dimensional figure;

Step 3: Calculate the long-term stable errors of the angular difference, the ratio difference, and the dielectric loss;

Step 4: Analyze the performance change of equipment from the same manufacturer, and discover the inherent defects of the equipment;

Step 5: Evaluate the comprehensive error of the measurement equipment by parameters such as transformer angular difference, ratio difference, electric energy meter error, secondary circuit voltage drop and the like;

Step 6: Calculate the voltage drop of the long-distance transmission line according to the data acquired synchronously by the entire network, and evaluate the line loss and the line parameters. Evaluate the transformer error by the difference between the secondary values of the transformers between two substations.

When performing on-line live calibration of a voltage transformer, the main principle is to calibrate other voltage transformers of the same voltage level by using an existing highly reliable voltage transformer as the standard. When performing online error calibration, the traceable standard transformer mainly comes from off-line calibrated bus PT; off-line calibrated main transformer CVT, and group calibration using all voltage transformers form a group and use each other as the standard.

When on-line live calibration of an electric energy meter is performed, the calibration time is dynamically determined based on the current value to ensure that the electric energy meter is calibrated in the full current range.

The purpose, technical schemes and benefits of this invention are further described in details in the specific embodiments described above. It should be understood that the above description is only illustrative of specific embodiments of the invention, and is not intended to limit the scope of the invention. Any modifications, equivalent substitutions, improvements, etc., made within the spirit and scope of the present invention are intended to be included within the scope of the present invention.

1. The on-line monitoring system for the performance of the measurement equipment in the entire power grid based on wide-area synchronous measurement includes a number of capacitive voltage transformers (CVT), electronic voltage transformers (EVT), electronic current transformers (ECT), electromagnetic potential transformers (PT), electromagnetic current transformers (CT), secondary circuits, electric energy meters, energy acquisition terminals, merging units, switches, clock synchronization systems, long-distance transmission line and other operating equipment. It also includes CVT insulation parameter monitoring module, CT oil pressure sensor, environmental parameter monitoring module, clock synchronization module, wide-area synchronous monitoring system consist of online monitoring apparatus, data transmission channel, installed in all substations of the power grid, as well as analysis and evaluation system of acquisition master station. The said online monitoring apparatus is the core of the system, which acquires the secondary voltage and current values of PT and CT, receives synchronous sampling values of EVT and ECT, receives the synchronous samplings from CVT insulation parameter monitoring module, CT oil pressure sensor and environmental parameter monitoring module, and stores and uploads to the monitoring master station after relevant calculations, meanwhile completes the online calibration of the energy meters.
The said online monitoring apparatus comprises CPU processor, first FPGA chip, second FPGA chip, clock unit, signal conditioning and A/D conversion unit, communication module, memory, etc. The two FPGA chips may be replaced by one single FPGA chip in case the single FPAG chip has enough resources. The first FPGA chip, the second FPGA chip and the clock unit are all connected with the CPU processor; the A/D conversion unit is connected with the first FPGA chip; the analog secondary circuits of the said CVT, PT, and CT are connected with the A/D conversion unit after signal conditioning; EVT and ECT are connected with merging unit; the merging unit is connected to the switches according to the voltage levels; the switch output end is connected with the second FPGA chip in the online monitoring apparatus. CVT insulation parameter acquisition module, CT oil pressure sensor and environmental parameter monitoring module are connected with merging unit, the merging unit is connected to the switches according to the voltage levels; the switch output end is connected with the second FPGA chip in the online monitoring apparatus. The output pulse of the said electric energy meter is connected to the first FPGA chip, and the first FPGA chip generates standard pulses according to the calculated energy; the clock synchronization module is connected with the merging unit and the clock unit in the on-line monitoring apparatus respectively to ensure synchronized data acquisition for the entire substation; CPU processor controls RJ45, USB, RS485, ST, SC interfaces through communication control module, and communicate with related equipment after data encryption through EASM;
The CPU of the instrumentational transformer online monitoring apparatus synchronously sampled and calculated the errors, insulation and environmental parameters of each transformer through the first and second FPGA chips. It connects with the energy data acquisition terminal through RS485 interface. The energy data acquisition terminal transmitted data to the acquisition master station through optical fiber and wireless private network. Meanwhile, the CPU can be directly connected with the central master station for equipment state evaluation through optical fiber and wireless module. The central master station evaluates and analyses the operation performance of the measurement equipment according to the received data. The on-line monitoring apparatus and merging unit are synchronized by clock synchronization module, and the on-line monitoring apparatus and merging unit in the entire network are synchronized by GPS clock synchronization system, so that the data of the entire network can be acquired synchronously.

2. According to claim 1, the said on-line monitoring system for the performance of the measurement equipment based on wide-area synchronous measurement is characterized by that the CPU, the first FPGA chip and the second FPGA chip of the said online monitoring apparatus are connected with RAM, and the first and the second FPGA chips are connected with each other, and each FPGA chip call the data stored in any RAM to calculate the relevant parameters.

3. According to claim 1 or 2, the said on-line monitoring system for the performance of the measurement equipment based on wide-area synchronous measurement, is characterized by 8-channel 24-bit ADS 1278 for the said A/D conversion unit, EP4CE10E2217 for the said first and second FPGA chips, H57V2562 for the said RAM, and AM3359 for the said CPU.

4. According to claim 1, the said on-line monitoring system for the performance of the measurement equipment based on wide-area synchronous measurement, is characterized by the steps of parameter sampling and calculation of the said CPU processor, including:
Step 1: Synchronously acquire the instantaneous values of 10 continuous cycles of up to 90 CVTs, PTs and CTs. The acquisition sampling frequency shall be above 256 points/cycle. The secondary amplitude and phase of each transformer, the effective current/voltage value of each circuit, and the secondary voltage drop of electromagnetic potential transformer PT shall be calculated. The accuracy of analog measurement shall be 0.05%, the resolution shall be 0.01%. The time interval of acquisition and analysis is 5 minutes;
Step 2: Analyze CVT capacitive current and ambient temperature and humidity parameters, which are digitized locally and uploaded by merging unit. The instantaneous values of CVT and PT in the same phase are used to calculate dielectric loss and capacitance.
Step 3: Calculate the short-term electric energy by using the instantaneous values of the voltage transformer and the current transformer. Calibrate the error of the electric energy meters by inspecting the low-frequency pulses of the electric energy meters. The calibration time is determined dynamically according to the current magnitude to ensure the accurate calibration of the meter in the full current range.
Step 4: According to the comparison of the vector sum of three-phase current of the same voltage level with the zero-sequence current, determine whether the error of the current transformer is out of tolerance;
Step 5: Configure the amplitude difference, phase difference and channels for dielectric loss calculation between any two transformers of the same voltage level. All acquired data is time stamped for storage.

5. According to claim 1, the said on-line monitoring system for the performance of the measurement equipment based on wide-area synchronous measurement is characterized by the evaluation and analysis steps s of the acquisition master station, including:
Step 1: Set the alarm value range of each measured value and the difference of the same measured value, and send out alarm to relevant professional and management personnel through text message and APP according to the measured value;
Step 2: Analyze the three-dimensional relationship between angular difference, ratio difference, dielectric loss with temperature and humidity at any period to form a three-dimensional figure;
Step 3: Calculate the long-term stable errors of the angular difference, the ratio difference, and the dielectric loss;
Step 4: Analyze the performance change of equipment from the same manufacturer, and discover the inherent defects of the equipment;
Step 5: Evaluate the comprehensive error of the measurement equipment by parameters such as transformer angular difference, ratio difference, electric energy meter error, secondary circuit voltage drop and the like;
Step 6: Calculate the voltage drop of the long-distance transmission line according to the data acquired synchronously by the entire network, and evaluate the line loss and the line parameters. Evaluate the transformer error by the difference between the secondary values of the transformers between two substations.

6. According to claim 1, the said on-line monitoring system for the performance of the measurement equipment based on wide-area synchronous measurement is characterized by that the CPU can directly connect with the central master station for equipment state evaluation through the optical fiber and the wireless module to meet the professional requirements for operation and maintenance. It can also connect with the electric energy acquisition terminal through the RS485 interface, and establish data connection with the acquisition master station through energy acquisition terminal to meet the requirements of the metrology specialty.

7. According to claim 1, the said on-line monitoring system for the performance of the measurement equipment based on wide-area synchronous measurement is characterized by that the clock synchronization module is used to control synchronous sampling, and the time-keeping error of the online monitoring apparatus is less than 4 us/10 min.

8. According to claim 1, the said on-line monitoring system for the performance of the measurement equipment based on wide-area synchronous measurement is characterized by the adoption of IEC 61850-9-1 and IEC 61850-9-2 protocols and the customization of environmental communication between the merging unit and the second FPGA chip.
